(19) United States
(12) Patent Application Publication
(10) Pub. No.: US 2026/0305077 A1
(43) Pub. Date: Oct. 1, 2026

(54) DISPLAY PANEL AND DISPLAY APPARATUS

(71) Applicant: Hefei Visionox Technology Co., Ltd., Hefei (CN)

(72) Inventors: Wenyu ZENG, Hefei (CN); Zongzhi CHEN, Hefei (CN); Shundong BAO, Hefei (CN); Jingping ZHANG, Hefei (CN)

(73) Assignee: Hefei Visionox Technology Co., Ltd., Hefei (CN)

(21) Appl. No.: 19/391,997

(22) Filed: Nov. 17, 2025

(30) Foreign Application Priority Data
Nov. 25, 2024 (CN) 202411699546.0

(51) Int. Cl. H10K 59/122; H10K 59/131; H10K 102/00

(52) U.S. Cl. CPC H10K 59/122; H10K 59/131; H10K 2102/351

(57) ABSTRACT

The present disclosure provides a display panel and a display apparatus. The display panel includes a substrate, a pixel defining layer, an isolation structure, and a plurality of light-emitting devices. The pixel defining layer is disposed on one side of the substrate. The pixel defining layer includes a plurality of pixel openings. An edge of each pixel opening includes at least one first edge portion and a plurality of second edge portions, the at least one first edge portion extending in a first direction, and the second edge portions intersecting with the first edge portion. The isolation structure is disposed on one side of the substrate and encloses a plurality of isolation openings. Each light-emitting device includes a first electrode, and at least part of the first electrode is located in a corresponding isolation opening.

### CROSS-REFERENCE TO RELATED APPLICATIONS

This application claims priority to Chinese Patent Application No. 202411699546.0, filed on Nov. 25, 2024, which is incorporated herein by reference in its entirety.

### FIELD

The present disclosure relates to the field of display, and in particular to a display panel and a display apparatus.

### BACKGROUND

An organic light-emitting diode (OLED) is an organic thin-film electroluminescent device, which has received great attention and has been widely used in electronic display products thanks to its advantages such as low power consumption, high luminance, wide angle of view, high contrast, and enabling flexible display.

However, the usage performance of current display panels needs to be improved.

During the preparation of conventional OLED display panels, light-emitting pixel patterning is usually implemented by means of a fine metal mask (FMM). FMM technology is mature and has rich experience in mass production. However, FMM technology also has problems such as limited accuracy and high costs. Fine metal mask-free technology eliminates the limitations of conventional OLED processes on display size, resolution, and other screen performances, and has the advantages of high performance, full-size coverage, and agile delivery. Reference can be made to relevant contents of the fine metal mask-free technology recited in Chinese patents CN 118251982 A, CN 115666161 A, CN 116648095 A, CN 117062489 A, CN 118678742 A, CN 118785761 A, CN 115224220 A, CN 118678729 A, CN 118660529 A and CN 118660589 A.

### SUMMARY

An objective of the present disclosure is to provide a display panel and a display apparatus, which can improve the usage performance of existing display panels.

To achieve the above objective, the present disclosure provides a display panel including a substrate, a pixel defining layer, an isolation structure and a plurality of light-emitting devices. The pixel defining layer is disposed on one side of the substrate. The pixel defining layer includes a plurality of pixel openings. An edge of each pixel opening includes at least one first edge portion and a plurality of second edge portions, the at least one first edge portion extending in a first direction, and the second edge portions intersecting with the first edge portion. The isolation structure is disposed on one side of the substrate. The isolation structure encloses a plurality of isolation openings, and the isolation openings are in communication with corresponding pixel openings. Each light-emitting device includes a light-emitting functional layer and a first electrode sequentially stacked in a direction away from the substrate, and at least part of the first electrode is located in a corresponding isolation opening. A part of the first electrode located above the at least one first edge portion and overlapping the isolation structure has a first thickness, and parts of the first electrode located above the plurality of second edge portions have a second thickness that is not greater than the first thickness.

The present disclosure further provides a display apparatus including a display panel as described above.

The present disclosure is advantageous in that in the display panel and the display apparatus of the present disclosure, the overlap structure of the first electrode of the light-emitting device is modified to improve the overlap yield between the first electrode and the isolation structure and thus improve the yield of the display panel.

### BRIEF DESCRIPTION OF THE DRAWINGS

FIG. 1 is a schematic diagram of partitions of a display panel according to an embodiment of the present disclosure;

FIG. 2 is a schematic enlarged view of pixel openings within box A in FIG. 1;

FIG. 3 is a schematic diagram of a layered structure of a single-side overlap light-emitting device according to an embodiment of the present disclosure;

FIG. 4 is a schematic diagram of a planar structure of a single-side overlap first electrode and a corresponding pixel opening according to an embodiment of the present disclosure;

FIG. 5 is a schematic diagram of a distribution structure of isolation openings according to other embodiments of the present disclosure;

FIG. 6 is a schematic diagram of a layered structure of a double-side overlap light-emitting device according to another embodiment of the present disclosure;

FIG. 7 is a schematic diagram of a planar structure of a double-side overlap first electrode and a corresponding pixel opening according to another embodiment of the present disclosure;

FIG. 8 is a schematic diagram showing evaporation of the single-side overlap first electrode according to an embodiment of the present disclosure;

FIG. 9 is a schematic diagram showing evaporation of the double-side overlap first electrode according to another embodiment of the present disclosure;

FIG. 10 is a schematic diagram of a planar structure of a single-side-cut pixel opening according to another embodiment of the present disclosure;

FIG. 11 is a schematic diagram of a distribution structure of isolation openings according to another embodiment of the present disclosure;

FIG. 12 is a schematic diagram of function graphs of a first function and a second function according to an embodiment of the present disclosure; and

FIG. 13 is a schematic diagram of function graphs of a third function and a fourth function according to another embodiment of the present disclosure.

The components in the figures are denoted as follows:
Display panel 1; Active area AA;
Non-active area NA; Substrate 10;
Pixel defining layer 20; Pixel opening 21;
First edge portion 211; First straight portion 2111;
Second straight portion 2112; Second edge portion 212;
First polyline portion 2121; First polyline segment 21211;
Second polyline segment 21212; Second polyline portion 2122;
Third polyline segment 21221; Fourth polyline segment 21222;
Light-emitting device 30; Second electrode 31;
Main body portion 311; First overlap portion 312;
Third overlap segment 3121; Fourth overlap segment 3122;
Second overlap portion 313; First overlap segment 3131;
Second overlap segment 3132; Fifth overlap segment 3133;
Sixth overlap segment 3134; Light-emitting functional layer 32;
First electrode 33; First light-emitting device 30R;
Second light-emitting device 30G; Third light-emitting device 30B;
Isolation structure 40; Support portion 41;
Isolation portion 42; Isolation opening 43;
Bonding portion 44;
First opening 43R; Second opening 43G;
Third opening 43B; Encapsulation layer 50;
Encapsulation sub-portion 51; Nozzle 2.

### DETAILED DESCRIPTION OF THE EMBODIMENTS

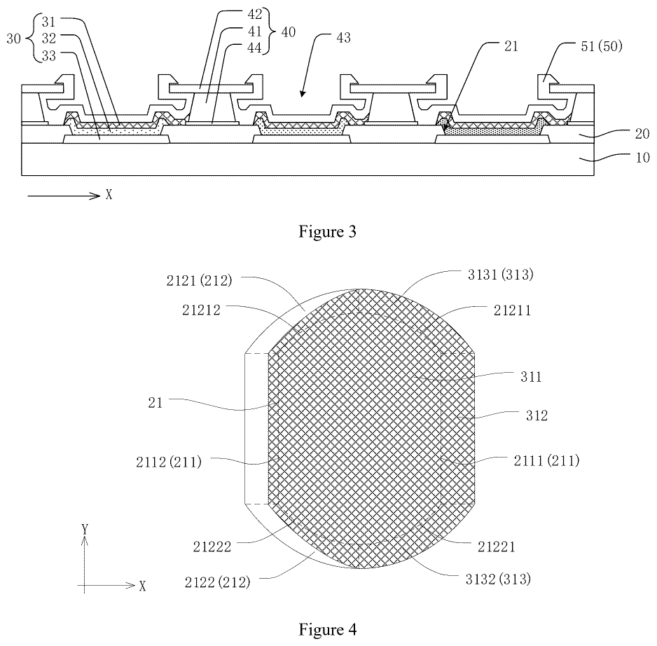

A display panel 1 is provided according to an embodiment of the present disclosure. As shown in FIG. 3, the display panel 1 further includes a substrate 10, an isolation structure 40, and light-emitting devices 30. The substrate 10 is configured to drive the light-emitting devices 30. The isolation structure 40 is disposed on one side of the substrate 10 and encloses a plurality of isolation openings 43, and is configured to block evaporation materials to disconnect the evaporation materials in adjacent isolation openings 43, to isolate various light-emitting devices 30. At least part of each light-emitting device 30 is disposed in a corresponding isolation opening 43. The light-emitting devices 30, as independent light-emitting units, can be driven by the substrate 10 to turn on or off according to corresponding display signals. Each light-emitting device 30 includes a first electrode 33. The first electrode 33 may be electrically connected to the isolation structure 40 to obtain a VSS power supply signal.

Specifically, as shown in FIG. 1, the display panel 1 of the present disclosure has an active area AA and a non-active area NA connected to the active area AA. A plurality of light-emitting devices 30 are provided in the active area AA, and each light-emitting device 30 independently emits light, thereby forming a display image in the active area AA. A driving device and a plurality of signal traces are provided in the non-active area NA. One end of each signal trace is electrically connected to the driving device, and the other end thereof extends to the active area AA and is electrically connected to the light-emitting device 30 located in the active area AA. The driving device may be an electronic device such as a flexible printed circuit (FPC) or a driver chip (IC). The driving device may send a display signal to the active area AA via the signal traces according to the display requirement, and the active area AA may then turn on corresponding light-emitting devices 30 according to the display signal, thereby controlling a display image.

As shown in FIG. 3, the substrate 10 is an array substrate, and includes thin film transistors arranged in an array and signal traces. Each light-emitting device 30 is electrically connected to at least one thin film transistor located in the active area AA. The driving device may be bonded to the substrate 10 in the non-active area NA by means of a COF (Chip On Film) process or an FOP (FPC On Panel) process, and the driving device is electrically connected to one ends of the signal traces. Each signal trace extends from the non-active area NA to the active area AA, and the other end thereof is electrically connected to the thin film transistor located in the active area AA. The driving device transmits the display signal to the corresponding thin film transistors via the signal traces, and the thin film transistors turn on the corresponding light-emitting devices 30 according to the display signal, to cause the light-emitting devices 30 at corresponding positions to emit light, thereby forming an image. Moreover, the driver chip may send different display signals to achieve a change of the display image.

The light-emitting device 30 is disposed on one side of the substrate 10, and includes a second electrode 31, a light-emitting functional layer 32, and a first electrode 33. The second electrode 31 is disposed on one side of the substrate 10 and is electrically connected to a corresponding thin film transistor in the substrate 10. The light-emitting functional layer 32 is located on a side of the second electrode 31 facing away from the substrate 10. The first electrode 33 is stacked on a side of the light-emitting functional layer 32 facing away from the substrate 10 and extends from the side of the light-emitting functional layer 32 facing away from the substrate 10 to a surface of the isolation structure 40 facing the isolation opening 43, to cause electrical connection between the first electrode 33 and the isolation structure 40.

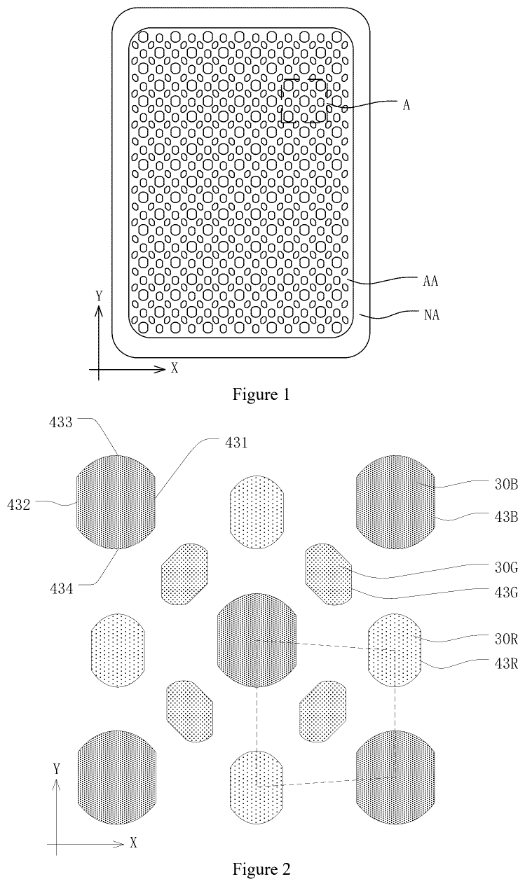

As shown in FIGS. 1 and 2, the display panel 1 has a plurality of light-emitting devices 30 capable of emitting light of different colors, namely first light-emitting devices 30R, second light-emitting devices 30G, and third light-emitting devices 30B. A wavelength of light emitted by the first light-emitting devices 30R is greater than wavelengths of light emitted by the second light-emitting devices 30G and by the third light-emitting devices 30B, and the wavelength of the light emitted by the second light-emitting devices 30G is greater than the wavelength of the light emitted by the third light-emitting devices 30B. For example, the first light-emitting device 30R may be configured to emit red light, the second light-emitting device 30G may be configured to emit green light, and the third light-emitting device 30B may be configured to emit blue light. The light-emitting devices 30 capable of emitting light of different colors may be uniformly distributed to display a color image. Specifically, in a second direction X and a first direction Y which are parallel to a plane where the substrate 10 is located and are perpendicular to each other, the first light-emitting devices 30R and the third light-emitting devices 30B are alternately arranged, and connecting lines between centers of two of the first light-emitting devices 30R and of two of the third light-emitting devices 30B form a virtual quadrilateral, and one of the second light-emitting devices 30G is located within the virtual quadrilateral. Further, a size of a pixel opening 21 in which a first light-emitting device 30R is provided is smaller than a size of a pixel opening 21 in which a second light-emitting device 30G is provided, and the size of the pixel opening 21 in which the second light-emitting device 30G is provided is smaller than a size of a pixel opening 21 in which a third light-emitting device 30B is provided, thereby ensuring the light-emitting devices 30 of different colors to be similar in light emission efficiency and service life.

As shown in FIG. 3, the display panel 1 further includes a pixel defining layer 20 located on the same side of the substrate 10 as the light-emitting devices 30. The pixel defining layer 20 is disposed on a surface of the substrate 10 and covers edges of the second electrodes 31. A plurality of pixel openings 21 are formed in the pixel defining layer 20. Each pixel opening 21 runs through the pixel defining layer 20, and at least part of the light-emitting device 30 is disposed in the pixel opening 21. Specifically, part of a surface of the second electrode 31 is exposed in the corresponding pixel opening 21, the light-emitting functional layer 32 covers the exposed surface of the second electrode 31 in the corresponding pixel opening 21, and extends from the surface of the second electrode 31 to a side of the pixel defining layer 30 facing away from the substrate 10.

Specifically, as shown in FIG. 4, an edge of the pixel opening 21 includes at least one first edge portion 211 and a plurality of second edge portions 212. In an embodiment of the present disclosure, the pixel opening 21 has one first edge portion 211, the first edge portion 211 extends in the first direction Y, and the second edge portions 212 intersect with the first edge portion 211. The first edge portion 211 includes a first straight portion 2111 and a second straight portion 2112, and the second edge portions 212 include a first polyline portion 2121 and a second polyline portion 2122. The first straight portion 2111 and the second straight portion 2112 extend in the first direction Y, the first polyline portion 2121 connects a first end of the first straight portion 2111 and a first end of the second straight portion 2112, and the second polyline portion 2122 connects a second end of the first straight portion 2111 and a second end of the second straight portion 2112, thereby forming a pixel opening 21 that is closed on all sides.

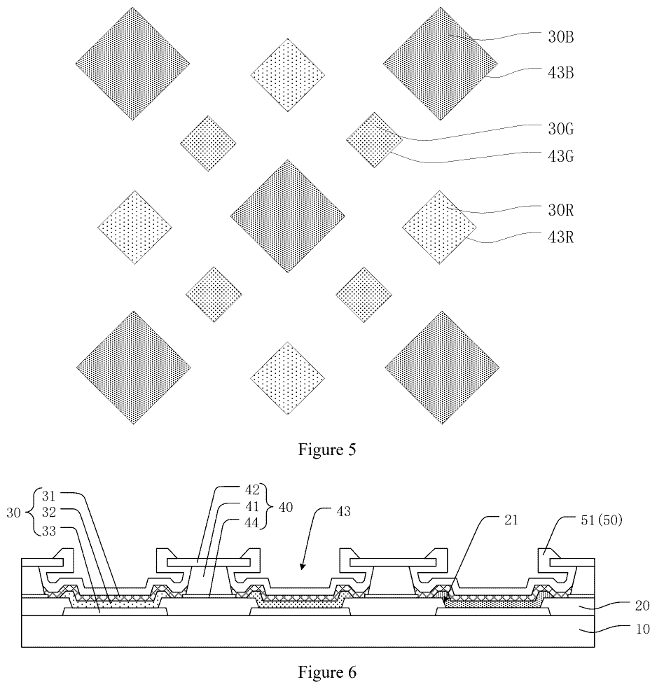

As shown in FIG. 3, the isolation structure 40 is arranged on the side of the pixel defining layer 20 facing away from the substrate 10, and includes a support portion 41, an isolation portion 42, and isolation openings 43. The support portion 41 is disposed on the side of the pixel defining layer 20 facing away from the substrate 10, the isolation portion 42 is stacked on a side of the support portion 41 facing away from the substrate 10, and the isolation opening 43 runs through the support portion 41 and the isolation portion 42 and is in communication with the corresponding pixel opening 21 to enable part of the material in the light-emitting device 30 to be evaporated in the pixel opening 21. The support portion 41 and the isolation portion 42 are each made of a material including a metal material, and the first electrode 33 extends from a surface of the light-emitting functional layer 32 to a side wall of the support portion 41 facing the isolation opening 43 and is thus electrically connected to the support portion 41. As shown in FIGS. 2 and 3, corresponding to the pixel openings 21 of different sizes, the isolation openings 43 also include first openings 43R, second openings 43G, and third openings 43B. At least part of the first light-emitting device is located in the first opening 43R, at least part of the second light-emitting device is located in the second opening 43G, at least part of the third light-emitting device is located in the third opening 43B, an aperture of the second opening 43G is smaller than apertures of the first opening 43R and of the third opening 43B, and the aperture of the first opening 43R is smaller than the aperture of the third opening 43B. An orthographic projection of the isolation opening 43 on the substrate 10 is a polygon, and in the first direction Y, widths of the isolation opening 43 at both ends are less than a width at the middle position thereof. In other embodiments of the present disclosure, the isolation opening 43 may also be in the shape of a quadrilateral as shown in FIG. 5, such as at least one of a right-angled quadrilateral, a rounded quadrilateral, or a chamfered quadrilateral. The quadrilateral isolation opening 43 has two mutually perpendicular diagonal lines which are respectively parallel to the second direction X and the first direction Y.

Further, the isolation structure 40 further includes bonding portions 44. Each bonding portion 44 is disposed on a side of the support portion 41 close to the substrate 10, and the bonding portion 44 protrudes from the support portion 41 toward the isolation opening 43. The overlap portion of the first electrode 33 also overlaps the bonding portion 44, and the bonding portion 44 is also made of a material including a metal material.

As shown in FIG. 3, an orthographic projection of the light-emitting functional layer 32 of the light-emitting device 30 on the substrate 10 does not overlap with an orthographic projection of the support portion 41 on the substrate 10, and there is a gap therebetween. In the second direction X, one side of the first electrode 33 extends from a surface of the light-emitting functional layer 32 facing away from the substrate 10 to the side wall of the support portion 41 facing the isolation opening 43 (the side wall also serves as a side wall of the isolation opening 43), and is electrically connected to the support portion 41, thereby forming a single-side overlap first electrode 33. The first electrode 33 may obtain a power supply signal via the support portion 41.

Specifically, a part of the first electrode 33 located above the first edge portion 211 and overlapping the isolation structure 40 has a first thickness, and parts of the first electrode 33 located above the plurality of second edge portions 212 have a second thickness that is not greater than the first thickness. As shown in FIG. 4, the first electrode 33 includes a main body portion 311 and an overlap portion. An orthographic projection of the main body portion 311 on the substrate 10 is outside the range of an orthographic projection of the isolation structure 40 on the substrate 10, and the orthographic projection of the main body portion 311 on the substrate 10 is outside the range of an orthographic projection of the isolation portion 42 on the substrate 10. The overlap portion is connected to the main body portion 311 and overlaps the isolation structure 40. An orthographic projection of the overlap portion on the substrate 10 is within the range of the orthographic projection of the isolation structure 40 on the substrate 10, and the orthographic projection of the overlap portion on the substrate 10 is within the range of the orthographic projection of the isolation portion 42 on the substrate 10. A part of the overlap portion located above the first edge portion 211 has the first thickness, and parts of the overlap portion located above the second edge portions 212 have the second thickness that is not greater than the first thickness, that is, the thickness of the overlap portion on both sides in the first direction Y is not greater than the thickness at its center position.

Further, in a display panel 1 according to an embodiment of the present disclosure, the light-emitting device 30 included therein is a single-side overlap light-emitting device, that is, the first electrode 33 of the light-emitting device 30 overlaps the isolation structure 40 on only one of the two sides in the second direction X to achieve electrical connection. The first electrode 33 of the single-side overlap light-emitting device 30 and the corresponding pixel opening 21 are specifically configured in the form that

a part of the first electrode 33 located above the first straight portion 2111 overlaps the isolation structure 40, a part of the first electrode 33 located above the second straight portion 2112 is spaced apart from the isolation structure 40, and the parts of the first electrode 33 located above the first straight portion 2111 and above the second straight portion 2112 have the first thickness.

The first polyline portion 2121 includes a first polyline segment 21211 and a second polyline segment 21212. Two ends of the first polyline segment 21211 are respectively connected to the second polyline segment 21212 and the first straight portion 2111. The second polyline segment 21212 is connected between the first polyline segment 21211 and the second straight portion 2112. An included angle between the first polyline segment 21211 and the first straight portion 2111 is greater than 90 degrees, and an included angle between the second polyline segment 21212 and the second straight portion 2112 is greater than 90 degrees. A part of the first electrode 33 located above the first polyline segment 21211 overlaps the isolation structure 40, a part of the first electrode 33 located above the second polyline segment 21212 is spaced apart from the isolation structure 40, and the part of the first electrode 33 located above the first polyline segment 21211 has the second thickness.

The second polyline portion 2122 includes a third polyline segment 21221 and a fourth polyline segment 21222. The third polyline segment 21221 is connected between the fourth polyline segment 21222 and the first straight portion 2111, and the fourth polyline segment 21222 is connected between the third polyline segment 21221 and the second straight portion 2112. An included angle between the third polyline segment 21221 and the first straight portion 2111 is greater than 90 degrees, and an included angle between the fourth polyline segment 21222 and the second straight portion 2112 is greater than 90 degrees. A part of the first electrode 33 located above the third polyline segment 21221 overlaps the isolation structure 40, a part of the first electrode 33 located above the fourth polyline segment 21222 is spaced apart from the isolation structure 40, and the part of the first electrode 33 located above the third polyline segment 21221 has the second thickness.

The overlap portion includes a first overlap portion 312 and a plurality of second overlap portions 313, and the first overlap portion 312 and the second overlap portions 313 may form an integral structure, thereby forming an integral overlap portion. The first overlap portion 312 is located above the first straight portion 2111. The plurality of second overlap portions 313 include a first overlap segment 3131 and a second overlap segment 3132. The first overlap segment 3131 is located above the first polyline segment 21211, and the second overlap segment 3132 is located above the third polyline segment 21221.

(“Above” in the above content does not refer to being directly above, but describes relative positions of various parts of the first electrode 33)

The main body portion 311 may have a maximum thickness in a range of 120 to 220 angstroms, and a thickness of an end of the main body portion 311 away from the first overlap portion 312 may be less than a thickness of the first overlap portion 312. The first overlap portion 312 has a thickness less than or equal to 220 angstroms. In one embodiment, the maximum thickness of the main body portion 311 and the maximum thickness of the first overlap portion 312 may be 150 angstroms. A thickness of an end of the second overlap portion 313 away from the first overlap portion 312 is greater than or equal to 0 angstroms and less than the thickness of the first overlap portion 312. A thickness of an end of the second overlap portion 313 connected to the first overlap portion 312 is less than or equal to the thickness of the first overlap portion 312 and greater than the thickness of the end thereof away from the first overlap portion 312. In one embodiment, as a spacing between the second overlap portion 313 and the first overlap portion 312 gradually decreases, a thickness of the second overlap portion 313 gradually increases, that is, in a direction toward the first overlap portion 312, the thickness of the second overlap portion 313 gradually increases from 0 angstroms to a thickness that is equal to or similar to the thickness of the first overlap portion 312 (e.g., less than or equal to 150 angstroms), and a function graph of the gradually increasing thickness of the second overlap portion 313 is consistent with arc form function graphs of a first arc and a second arc, and the thickness of the first electrode 33 at both ends is less than the thickness of the first electrode 33 at the middle position, thereby improving the effective overlap rate of the first electrode 33.

Further, starting from an end of the first polyline segment 21211 away from the first straight portion 2111, a decrease in a distance between the first polyline segment 21211 and the first straight portion 2111 in the second direction X and an increase in a length of the first polyline segment 21211 in the first direction Y satisfy a first function. Starting from an end of the first overlap segment 3131 away from the first overlap portion 312, a decrease in a distance between the first overlap segment 3131 and the first overlap portion 312 in the second direction X and an increase in a thickness of the first overlap segment 3131 in the first direction Y satisfy the first function. Starting from an end of the third polyline segment 21221 away from the first straight portion 2111, a decrease in a distance between the third polyline segment 21221 and the first straight portion 2111 in the second direction X and an increase in a length of the third polyline segment 21221 in the first direction Y satisfy a second function. Starting from an end of the second overlap segment 3132 away from the first overlap portion 312, a decrease in a distance between the second overlap segment 3132 and the first overlap portion 312 in the second direction X and an increase in a thickness of the second overlap segment 3132 in the first direction Y satisfy the second function. (Function graphs of the first function and the second function are shown in FIG. 12)

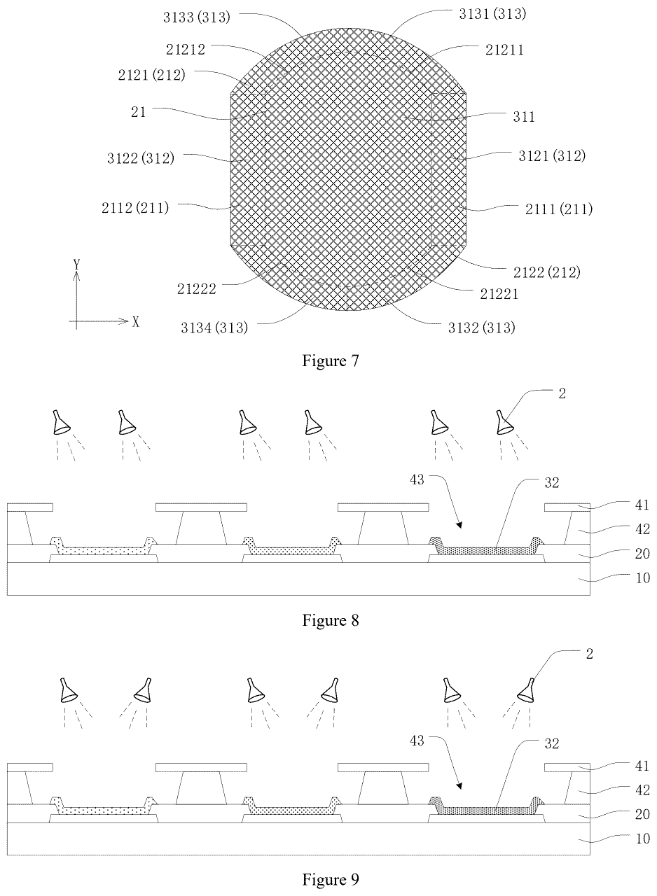

Further, in a display panel 1 according to another embodiment of the present disclosure, the light-emitting device 30 included therein may also be a double-side overlap light-emitting device, that is, as shown in FIG. 6, both sides of the first electrode 33 of the light-emitting device 30 in the second direction X overlap the isolation structure 40 to achieve electrical connection. As shown in FIG. 7, the first electrode 33 of the double-side overlap light-emitting device 30 and the corresponding pixel opening 21 are specifically configured in the form that

parts of the first electrode 33 located above the first straight portion 2111 and above the second straight portion 2112 overlap the isolation structure 40, and the parts of the first electrode 33 located above the first straight portion 2111 and above the second straight portion 2112 have the first thickness.

The first polyline portion 2121 includes a first polyline segment 21211 and a second polyline segment 21212. Two ends of the first polyline segment 21211 are respectively connected to the second polyline segment 21212 and the first straight portion 2111. The second polyline segment 21212 is connected between the first polyline segment 21211 and the second straight portion 2112. An included angle between the first polyline segment 21211 and the first straight portion 2111 is greater than 90 degrees, and an included angle between the second polyline segment 21212 and the second straight portion 2112 is greater than 90 degrees. Parts of the first electrode 33 located above the first polyline segment 21211 and above the second polyline segment 21212 overlap the isolation structure 40, and the parts of the first electrode 33 located above the first polyline segment 21211 and above the second polyline segment 21212 have the second thickness.

The second polyline portion 2122 includes a third polyline segment 21221 and a fourth polyline segment 21222. The third polyline segment 21221 is connected between the fourth polyline segment 21222 and the first straight portion 2111, and the fourth polyline segment 21222 is connected between the third polyline segment 21221 and the second straight portion 2112. An included angle between the third polyline segment 21221 and the first straight portion 2111 is greater than 90 degrees, and an included angle between the fourth polyline segment 21222 and the second straight portion 2112 is greater than 90 degrees. Parts of the first electrode 33 located above the third polyline segment 21221 and above the fourth polyline segment 21222 overlap the isolation structure 40, and the parts of the first electrode 33 located above the third polyline segment 21221 and above the fourth polyline segment 21222 have the second thickness.

The overlap portion includes a plurality of first overlap portions 312 and a plurality of second overlap portions 313. The first overlap portions 312 and the second overlap portions 313 may form an integral structure, thereby forming an integral overlap portion. The plurality of first overlap portions 312 include a third overlap segment 3121 and a fourth overlap segment 3122. The third overlap segment 3121 is located above the first straight portion 2111, and the fourth overlap segment 3122 is located above the second straight portion 2112. The plurality of second overlap portions 313 include a first overlap segment 3131, a second overlap segment 3132, a fifth overlap segment 3133 and a sixth overlap segment 3134. The first overlap segment 3131 is located above the first polyline segment 21211, the second overlap segment 3132 is located above the third polyline segment 21221, the fifth overlap segment 3133 is located above the second polyline segment 21212, and the sixth overlap segment 3134 is located above the fourth polyline segment 21222.

In this embodiment, the thickness of the main body portion 311 may be greater than the thickness of the first overlap portion 312. In one embodiment, due to the limitation of an evaporation process, the main body portion 311 has a thickness in a range of 120 to 220 angstroms, and the first overlap portion 312 has a thickness in a range of 60 to 110 angstroms, for example, the main body portion 311 may have a thickness of 150 angstroms, and the first overlap portion 312 may have a thickness less than or equal to 75 angstroms. A thickness of an end of the second overlap portion 313 away from the first overlap portion 312 is greater than or equal to 0 angstroms and less than the thickness of the first overlap portion 312, and a thickness of an end connected to the first overlap portion 312 is less than or equal to the thickness of the first overlap portion 312 and greater than the thickness of the end away from the first overlap portion 312. In one embodiment, as a spacing between the second overlap portion 313 and the first overlap portion 312 gradually decreases, a thickness of the second overlap portion 313 gradually increases, that is, in a direction toward the first overlap portion 312, the thickness of the second overlap portion 313 gradually increases from 0 angstroms to a thickness that is equal to or similar to the thickness of the first overlap portion 312 (e.g., less than or equal to 75 angstroms), and a function graph of the gradually increasing thickness of the second overlap portion 313 is consistent with arc form function graphs of a first arc and a second arc, and the thickness of the first electrode 33 at both ends is less than the thickness of the first electrode 33 at the middle position, thereby improving the effective overlap rate of the first electrode 33. Moreover, the double-side overlap first electrode can also prevent defects, such as cracks and recesses, in the surface of the pixel defining layer due to excessive etching of the pixel defining layer during the subsequent process of film layer manufacturing.

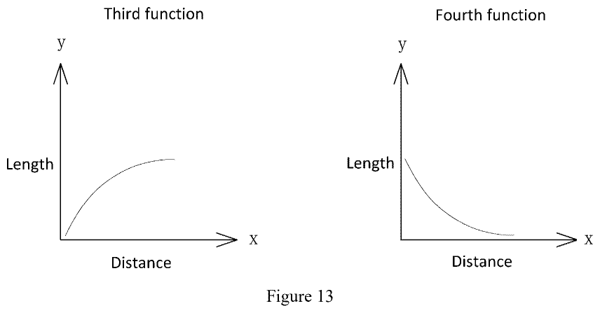

Further, starting from an end of the second polyline segment 21212 away from the second straight portion 2112, a decrease in a distance between the second polyline segment 21212 and the second straight portion 2112 in the second direction X and an increase in a length of the second polyline segment 21212 in the first direction Y satisfy a third function, the second direction X being perpendicular to the first direction Y. Starting from an end of the fifth overlap segment 3133 away from the fourth overlap segment 3122, a decrease in a distance between the fifth overlap segment 3133 and the fourth overlap segment 3122 in the second direction X and an increase in a thickness of the fifth overlap segment 3133 in the first direction Y satisfy the third function. Specifically, starting from an end of the fourth polyline segment 21222 away from the second straight portion 2112, a decrease in a distance between the fourth polyline segment 21222 and the second straight portion 2112 in the second direction X and an increase in a length of the fourth polyline segment 21222 in the first direction Y satisfy a fourth function. Starting from an end of the sixth overlap segment 3134 away from the fourth overlap segment 3122, a decrease in a distance between the sixth overlap segment 3134 and the fourth overlap segment 3122 in the second direction X and an increase in a thickness of the sixth overlap segment 3134 in the first direction Y satisfy the fourth function. (Function graphs of the third function and the fourth function are shown in FIG. 13)

Further, in other embodiments of the present disclosure, single-side overlap first electrodes and double-side overlap first electrodes can be used as desired according to actual needs, for example, all light-emitting devices are each provided with a single-side overlap first electrode, or all light-emitting devices are each provided with a double-side overlap first electrode, or some of the light-emitting devices are each provided with a single-side overlap first electrode and the remaining light-emitting devices are each provided with a double-side overlap first electrode.

Further, a contact area between parts of the overlap portion located above the plurality of second edge portions 212 and the isolation structure 40 is not greater than a contact area between a part of the overlap portion located above the at least one first edge portion 211 and the isolation structure 40, that is, a contact area between the second overlap portions 313 and the isolation structure 40 is not greater than a contact area between the first overlap portion 312 and the isolation structure 40. In one embodiment, the contact area between the second overlap portions 313 and the isolation structure 40 is smaller than the contact area between the first overlap portion 312 and the isolation structure 40. Moreover, the contact area between the parts of the overlap portion located above the plurality of second edge portions 212 and the isolation structure 40 gradually increases in the direction toward the first edge portion 211, that is, the contact area between the second overlap portions 313 and the isolation structure 40 gradually increases in the direction toward the first overlap portion 312.

Further, an orthographic projection of the isolation portion 42 on the substrate 10 covers an orthographic projection of the support portion 41 on the substrate 10, and an area of the orthographic projection of the isolation portion 42 on the substrate 10 is larger than an area of the orthographic projection of the support portion 41 on the substrate 10, and the isolation portion 42 can completely cover the support portion 41, which can thus prevent the material of the light-emitting functional layer 32 from being evaporated onto the support portion 41 during preparation of the light-emitting functional layer 32. In addition, during preparation of the first electrode 33, a material evaporation angle of the first electrode 33 can be adjusted to cause a coverage area of the first electrode 33 to be larger than that of the light-emitting functional layer 32, and the first electrode 33 can extend from the surface of the light-emitting functional layer 32 facing away from the substrate 10 to the side wall of the support portion 41 facing the isolation opening 43, to facilitate overlapping of the first electrode 33 and the support portion 41. Specifically, during preparation of a light-emitting device 30 having a single-side overlap first electrode 33, as shown in FIG. 8, all nozzles 2 in an evaporation apparatus for preparing the first electrode 33 may be tilted toward the side of the first straight portion 2111 of the pixel opening 21, and all the nozzles 2 face the side wall of the support portion 41 corresponding to the first straight portion 2111, and the material sprayed from the nozzles 2 can be deposited on the side wall of the support portion 41 corresponding to the first straight portion 2111. During preparation of a light-emitting device 30 having a double-side overlap first electrode 33, as shown in FIG. 9, some of nozzles 2 in an evaporation apparatus for preparing the first electrode 33 may be tilted toward the side of the first straight portion 2111 of the pixel opening 21, and some are tilted toward the side of the second straight portion 2112, and some of the nozzles 2 face the side wall of the support portion 41 corresponding to the first straight portion 2111, and some of the nozzles 2 face the side wall of the support portion 41 corresponding to the second straight portion 2112, and the material sprayed from the nozzles 2 can be deposited on the side walls of the support portion 41 corresponding to the first straight portion 2111 and the second straight portion 21122.

An encapsulation layer 50 is disposed on a side of the light-emitting device 30 facing away from the substrate 10, and an orthographic projection of the encapsulation layer 50 on the substrate 10 covers an orthographic projection of the light-emitting device 30 on the substrate 10. The encapsulation layer 50 includes a plurality of encapsulation sub-portions 51, and at least one encapsulation sub-portion 51 is provided in each isolation opening 43. Specifically, each encapsulation sub-portion 51 extends from a surface of the first electrode 33 facing away from the substrate 10 to a side of the isolation structure 40 facing away from the substrate 10. The encapsulation layer 50 is used to encapsulate and protect the display device in the display panel 1, is made of a material including an inorganic material, and may be prepared by a chemical vapor deposition (CVD) process.

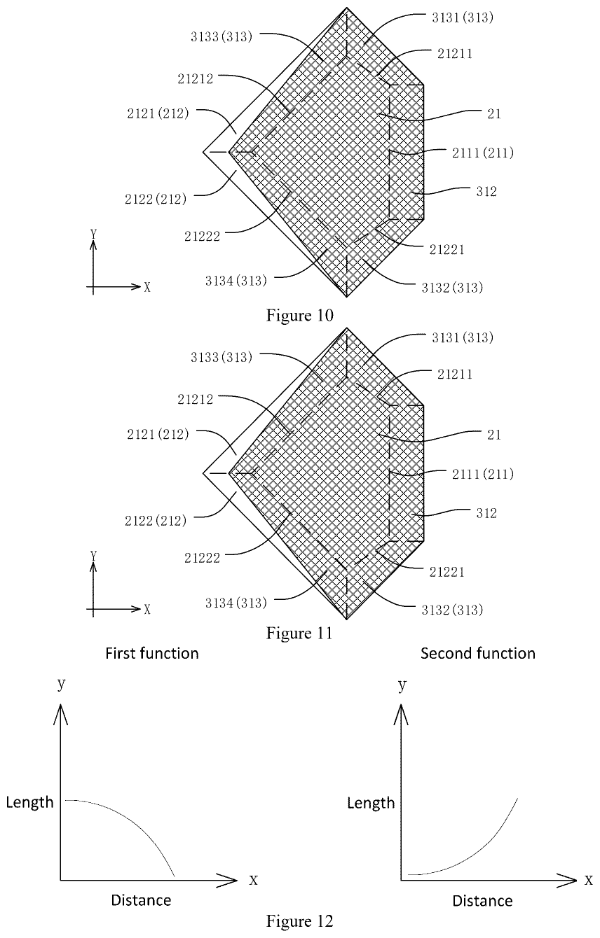

Further, in a display panel 1 according to an embodiment of the present disclosure, its pixel opening 21 is of a double-edge-cut (double-straight-side) structure having a first straight portion 2111 and a second straight portion 2112 arranged opposite each other. However, in another embodiment of the present disclosure, the pixel opening 21 may be of a single-edge-cut (single-straight-side) structure, and the first electrode 33 of the light-emitting device 30 arranged in the pixel opening 21 may also be a single-side overlap first electrode. As shown in FIG. 10, the single-cut-side pixel opening 21 and the corresponding first electrode 33 are specifically configured in the form that

an edge of the pixel opening 21 includes at least one first edge portion 211 and a plurality of second edge portions 212, and in this embodiment, the pixel opening 21 has one first edge portion 211, the first edge portion 211 extends in the first direction Y, and the second edge portions 212 intersect with the first edge portion 211. The first edge portion 211 includes a first straight portion 2111, and the second edge portions 212 include a first polyline portion 2121 and a second polyline portion 2122. The first straight portion 2111 extends in the first direction Y, two ends of the first polyline portion 2121 are respectively connected to a first end of the first straight portion 2111 and the second polyline portion 2122, and two ends of the second polyline portion 2122 are respectively connected to a second end of the first straight portion 2111 and the first polyline portion 2121, thereby forming a polygonal pixel opening 21 that is closed on all sides.

A part of the first electrode 33 located above the first straight portion 2111 overlaps the isolation structure 40, and the part of the first electrode 33 located above the first straight portion 2111 has the first thickness.

The first polyline portion 2121 includes a first polyline segment 21211 and a second polyline segment 21212. Two ends of the first polyline segment 21211 are respectively connected to the second polyline segment 21212 and the first straight portion 2111, two ends of the second polyline segment 21212 are respectively connected to the first polyline segment 21211 and the second polyline portion 2122, and an included angle between the first polyline segment 21211 and the first straight portion 2111 is greater than 90 degrees. A part of the first electrode 33 located above the first polyline segment 21211 overlaps the isolation structure 40, and the part of the first electrode 33 located above the first polyline segment 21211 has the second thickness.

The second polyline portion 2122 includes a third polyline segment 21221 and a fourth polyline segment 21222. Two ends of the third polyline segment 21221 are respectively connected to the fourth polyline segment 21222 and the first straight portion 2111, two ends of the fourth polyline segment 21222 are respectively connected to the third polyline segment 21221 and the first polyline portion 2121, and an included angle between the third polyline segment 21221 and the first straight portion 2111 is greater than 90 degrees. A part of the first electrode 33 located above the third polyline segment 21221 overlaps the isolation structure 40, and the part of the first electrode 33 located above the third polyline segment 21221 has the second thickness.

Further, in this embodiment, the overlap portion of the first electrode 33 includes a first overlap portion 312 and a plurality of second overlap portions 313, and the first overlap portion 312 and the second overlap portion 313 may also form an integral structure. The first overlap portion 312 is located above the first straight portion 2111. The second overlap portions 313 include a first overlap segment 3131, a second overlap segment 3132, a fifth overlap segment 3133, and a sixth overlap segment 3134. The first overlap segment 3131 is located above the first polyline segment 21211, the second overlap segment 3132 is located above the third polyline segment 21221, the fifth overlap segment 3133 is located above the second polyline segment 21212, and the sixth overlap segment 3134 is located above the fourth polyline segment 21222. A thickness of an end of the second overlap portion 313 away from the first overlap portion 312 is greater than or equal to 0 angstroms and less than the thickness of the first overlap portion 312. A thickness of an end of the second overlap portion 313 connected to the first overlap portion 312 is less than or equal to the thickness of the first overlap portion 312 and greater than the thickness of the end of the second overlap portion 313 away from the first overlap portion 312. In addition, the second overlap portion 313 has a thickness gradually increasing in the direction toward the first overlap portion 312, and the thickness of the first electrode 33 at both ends is less than the thickness of the first electrode 33 at the middle position, thereby improving the effective overlap rate of the first electrode 33.

Further, as shown in FIG. 11, in this embodiment, the isolation opening 43 in the display panel 1 may also be formed in a similar opening shape according to the structure of the pixel opening 21 described above. In addition, the arrangement of the light-emitting devices 30 of different colors and the isolation openings 43 of different sizes in the display panel 1 may be the same as that in the display panel described above, and thus will not be repeated herein.

A display apparatus is further provided in another embodiment of the present disclosure. The display apparatus may be an OLED display apparatus including any of the display panels 1 described above. The display apparatus may be any display device with a display function, such as a mobile phone, a laptop, or a tablet computer.

Although the present disclosure is described herein with reference to the specific implementations, it should be understood that these embodiments are merely illustrative of the principles and applications of the present disclosure. It should therefore be understood that many modifications can be made to the illustrative embodiments and that other arrangements can be devised without departing from the spirit and scope of the present disclosure as defined by the appended claims. It should be understood that the various dependent claims and features described herein can be combined in ways other than as described in the original claims. It should also be understood that the features described with reference to a single embodiment can be used in other embodiments described.

1. A display panel, comprising:
a substrate;
a pixel defining layer disposed on one side of the substrate, the pixel defining layer comprising a plurality of pixel openings, an edge of each of the pixel openings comprising at least one first edge portion and a plurality of second edge portions, the at least one first edge portion extending in a first direction, and the second edge portions intersecting with the first edge portion;
an isolation structure disposed on one side of the substrate, the isolation structure enclosing a plurality of isolation openings, and the isolation openings being in communication with corresponding pixel openings; and
a plurality of light-emitting devices each comprising a light-emitting functional layer and a first electrode sequentially stacked in a direction away from the substrate, at least part of the first electrode being located in a corresponding isolation opening;
wherein a part of the first electrode located above the at least one first edge portion and overlapping the isolation structure has a first thickness, and parts of the first electrode located above the plurality of second edge portions have a second thickness that is not greater than the first thickness.

2. The display panel according to claim 1, wherein the parts of the first electrode located above the plurality of second edge portions and overlapping the isolation structure have the second thickness, and the first electrode comprises:
a main body portion, an orthographic projection of the main body portion on the substrate being outside the range of an orthographic projection of the isolation structure on the substrate; and
an overlap portion connected to the main body portion and overlapping the isolation structure, an orthographic projection of the overlap portion on the substrate being within the range of the orthographic projection of the isolation structure on the substrate;
wherein a part of the overlap portion located above the at least one first edge portion has the first thickness, and parts of the overlap portion located above the plurality of second edge portions have the second thickness.

3. The display panel according to claim 2, wherein the isolation structure comprises:
a support portion disposed on one side of the substrate; and
an isolation portion disposed on a side of the support portion facing away from the substrate, the isolation portion protruding from the support portion toward the isolation openings;
wherein the orthographic projection of the main body portion on the substrate is outside the range of an orthographic projection of the isolation portion on the substrate, and the orthographic projection of the overlap portion on the substrate is within the range of the orthographic projection of the isolation portion on the substrate.

4. The display panel according to claim 2, wherein the at least one first edge portion comprises a first straight portion and a second straight portion, and the plurality of second edge portions comprise a first polyline portion and a second polyline portion, wherein the first straight portion and the second straight portion extend in the first direction; and the first polyline portion connects a first end of the first straight portion and a first end of the second straight portion, and the second polyline portion connects a second end of the first straight portion and a second end of the second straight portion; and
wherein a part of the first electrode located above the first straight portion overlaps the isolation structure and has the first thickness, and a part of the first electrode located above the second straight portion is spaced apart from the isolation structure.

5. The display panel according to claim 4, wherein the first polyline portion comprises a first polyline segment and a second polyline segment, and the second polyline portion comprises a third polyline segment and a fourth polyline segment, wherein
the first polyline segment is connected between the second polyline segment and the first straight portion, the second polyline segment is connected between the first polyline segment and the second straight portion, an included angle between the first polyline segment and the first straight portion is greater than 90 degrees, and an included angle between the second polyline segment and the second straight portion is greater than 90 degrees; and
the third polyline segment is connected between the fourth polyline segment and the first straight portion, the fourth polyline segment is connected between the third polyline segment and the second straight portion, an included angle between the third polyline segment and the first straight portion is greater than 90 degrees, and an included angle between the fourth polyline segment and the second straight portion is greater than 90 degrees; and
wherein a part of the first electrode located above the first polyline segment overlaps the isolation structure and has the second thickness, a part of the first electrode located above the second polyline segment is spaced apart from the isolation structure, a part of the first electrode located above the third polyline segment overlaps the isolation structure and has the second thickness, and a part of the first electrode located above the fourth polyline segment is spaced apart from the isolation structure.

6. The display panel according to claim 5, wherein the overlap portion comprises:
a first overlap portion located above the first straight portion;
a plurality of second overlap portions comprising a first overlap segment and a second overlap segment, the first overlap segment being located above the first polyline segment, and the second overlap segment being located above the third polyline segment;
wherein the first overlap portion and the plurality of second overlap portions form an integral structure; and
a thickness of an end of the second overlap portion away from the first overlap portion is greater than or equal to 0 angstroms and less than a thickness of the first overlap portion; and a thickness of an end of the second overlap portion connected to the first overlap portion is less than or equal to the thickness of the first overlap portion and greater than the thickness of the end of the second overlap portion away from the first overlap portion.

7. The display panel according to claim 6, wherein the second overlap portion has a thickness gradually increasing in a direction toward the first overlap portion;
the main body portion and the first overlap portion each has a thickness less than or equal to 220 angstroms; and
a thickness of an end of the main body portion away from the first overlap portion is less than the thickness of the first overlap portion.

8. The display panel according to claim 6, wherein
starting from an end of the first polyline segment away from the first straight portion, a decrease in a distance between the first polyline segment and the first straight portion in the second direction and an increase in a length of the first polyline segment in the first direction satisfy a first function, the second direction being perpendicular to the first direction;
starting from an end of the first overlap segment away from the first overlap portion, a decrease in a distance between the first overlap segment and the first overlap portion in the second direction and an increase in a thickness of the first overlap segment in the first direction satisfy the first function;
starting from an end of the third polyline segment away from the first straight portion, a decrease in a distance between the third polyline segment and the first straight portion in the second direction and an increase in a length of the third polyline segment in the first direction satisfy a second function; and
starting from an end of the second overlap segment away from the first overlap portion, a decrease in a distance between the second overlap segment and the first overlap portion in the second direction and an increase in a thickness of the second overlap segment in the first direction satisfy the second function.

9. The display panel according to claim 2, wherein the at least one first edge portion comprises a first straight portion and a second straight portion, and the plurality of second edge portions comprise a first polyline portion and a second polyline portion, wherein the first straight portion and the second straight portion extend in the first direction; and the first polyline portion connects a first end of the first straight portion and a first end of the second straight portion, and the second polyline portion connects a second end of the first straight portion and a second end of the second straight portion; and
wherein parts of the first electrode located above the first straight portion and above the second straight portion overlap the isolation structure and have the first thickness.

10. The display panel according to claim 9, wherein the first polyline portion comprises a first polyline segment and a second polyline segment, and the second polyline portion comprises a third polyline segment and a fourth polyline segment, wherein
the first polyline segment is connected between the second polyline segment and the first straight portion, the second polyline segment is connected between the first polyline segment and the second straight portion, an included angle between the first polyline segment and the first straight portion is greater than 90 degrees, and an included angle between the second polyline segment and the second straight portion is greater than 90 degrees; and
the third polyline segment is connected between the fourth polyline segment and the first straight portion, the fourth polyline segment is connected between the third polyline segment and the second straight portion, an included angle between the third polyline segment and the first straight portion is greater than 90 degrees, and an included angle between the fourth polyline segment and the second straight portion is greater than 90 degrees; and
wherein parts of the first electrode located above the first polyline segment and above the second polyline segment overlap the isolation structure and have the second thickness, and parts of the first electrode located above the third polyline segment and above the fourth polyline segment overlap the isolation structure and have the second thickness.

11. The display panel according to claim 10, wherein the overlap portion comprises:
a plurality of first overlap portions comprising a third overlap segment and a fourth overlap segment, the third overlap segment being located above the first straight portion, and the fourth overlap segment being located above the second straight portion; and
a plurality of second overlap portions comprising a first overlap segment, a second overlap segment, a fifth overlap segment, and a sixth overlap segment, the first overlap segment being located above the first polyline segment, the second overlap segment being located above the third polyline segment, the fifth overlap segment being located above the second polyline segment, and the sixth overlap segment being located above the fourth polyline segment;
wherein the plurality of first overlap portions and the plurality of second overlap portions form an integral structure;
a thickness of an end of the second overlap portion away from the first overlap portion is greater than or equal to 0 angstroms and less than a thickness of the first overlap portion; and a thickness of an end of the second overlap portion connected to the first overlap portion is less than or equal to the thickness of the first overlap portion and greater than the thickness of the end of the second overlap portion away from the first overlap portion.

12. The display panel according to claim 11, wherein the second overlap portion has a thickness gradually increasing in a direction toward the first overlap portion;
the main body portion has a maximum thickness less than or equal to 220 angstroms;
the first overlap portion has a maximum thickness less than or equal to 110 angstroms; and
a thickness of an end of the main body portion away from the first overlap portion is less than the thickness of the first overlap portion.

13. The display panel according to claim 11, wherein
starting from an end of the second polyline segment away from the second straight portion, a decrease in a distance between the second polyline segment and the second straight portion in the second direction and an increase in a length of the second polyline segment in the first direction satisfy a third function, the second direction being perpendicular to the first direction;
starting from an end of the fifth overlap segment away from the fourth overlap segment, a decrease in a distance between the fifth overlap segment and the fourth overlap segment in the second direction and an increase in a thickness of the fifth overlap segment in the first direction satisfy the third function;
starting from an end of the fourth polyline segment away from the second straight portion, a decrease in a distance between the fourth polyline segment and the second straight portion in the second direction and an increase in a length of the fourth polyline segment in the first direction satisfy a fourth function; and
starting from an end of the sixth overlap segment away from the fourth overlap segment, a decrease in a distance between the sixth overlap segment and the fourth overlap segment in the second direction and an increase in a thickness of the sixth overlap segment in the first direction satisfy the fourth function.

14. The display panel according to claim 2, wherein the at least one first edge portion comprises a first straight portion, and the plurality of second edge portions comprise a first polyline portion and a second polyline portion, wherein
the first straight portion extends in the first direction;
the first polyline portion connects a first end of the first straight portion and the second polyline portion, and the second polyline portion connects a second end of the first straight portion and the first polyline portion; and
wherein a part of the first electrode located above the first straight portion overlaps the isolation structure and has the first thickness.

15. The display panel according to claim 14, wherein the first polyline portion comprises a first polyline segment and a second polyline segment, and the second polyline portion comprises a third polyline segment and a fourth polyline segment, wherein
the first polyline segment is connected between the second polyline segment and the first straight portion, the second polyline segment is connected between the first polyline segment and the second polyline portion, and an included angle between the first polyline segment and the first straight portion is greater than 90 degrees; and
the third polyline segment is connected between the fourth polyline segment and the first straight portion, the fourth polyline segment is connected between the third polyline segment and the first polyline portion, and an included angle between the third polyline segment and the first straight portion is greater than 90 degrees; and wherein a part of the first electrode located above the first polyline segment overlaps the isolation structure and has the second thickness, and a part of the first electrode located above the third polyline segment overlaps the isolation structure and has the second thickness.

16. The display panel according to claim 15, wherein the overlap portion comprises:
a first overlap portion located above the first straight portion;
a plurality of second overlap portions comprising a first overlap segment, a second overlap segment, a fifth overlap segment and a sixth overlap segment, the first overlap segment being located above the first polyline segment, the second overlap segment being located above the third polyline segment, the fifth overlap segment being located above the second polyline segment, and the sixth overlap segment being located above the fourth polyline segment;
wherein the first overlap portion and the plurality of second overlap portions form an integral structure;
a thickness of an end of the second overlap portion away from the first overlap portion is greater than or equal to 0 angstroms and less than a thickness of the first overlap portion; a thickness of an end of the second overlap portion connected to the first overlap portion is less than or equal to the thickness of the first overlap portion and greater than the thickness of the end of the second overlap portion away from the first overlap portion; and
the second overlap portion has a thickness gradually increasing in a direction toward the first overlap portion.

17. The display panel according to claim 1, wherein the plurality of light-emitting devices comprise a plurality of first light-emitting devices, a plurality of second light-emitting devices, and a plurality of third light-emitting devices;
wherein the first light-emitting devices and the third light-emitting devices are alternately arranged in the first direction and in the second direction;
connecting lines between centers of two of the first light-emitting devices and of two of the third light-emitting devices form a virtual quadrilateral, and one of the second light-emitting devices is located within the virtual quadrilateral;
a wavelength of light emitted by the first light-emitting devices is greater than wavelengths of light emitted by the second light-emitting devices and by the third light-emitting devices; and
the wavelength of the light emitted by the second light-emitting devices is greater than the wavelength of the light emitted by the third light-emitting devices.

18. The display panel according to claim 17, wherein the plurality of isolation openings comprise:
a plurality of first openings, at least part of the first light-emitting device being located in a corresponding a first opening;
a plurality of second openings, at least part of the second light-emitting device being located in a corresponding a second opening; and
a plurality of third openings, at least part of the third light-emitting device being located in a corresponding a third opening;
wherein an aperture of each of the second openings is smaller than an aperture of each of the first openings and the third openings; and
the aperture of the first opening is smaller than the aperture of the third opening.

19. The display panel according to claim 2, wherein
a contact area between parts of the overlap portion located above the plurality of second edge portions and the isolation structure is not greater than a contact area between a part of the overlap portion located above the at least one first edge portion and the isolation structure; and
the contact area between the parts of the overlap portion located above the plurality of second edge portions and the isolation structure gradually increases in a direction toward the first edge portion.

20. A display apparatus, comprising:
a display panel, comprising:
a substrate;
a pixel defining layer disposed on one side of the substrate, the pixel defining layer comprising a plurality of pixel openings, an edge of each of the pixel openings comprising at least one first edge portion and a plurality of second edge portions, the at least one first edge portion extending in a first direction, and the second edge portions intersecting with the first edge portion;
an isolation structure disposed on one side of the substrate, the isolation structure enclosing a plurality of isolation openings, and the isolation openings being in communication with corresponding pixel openings; and
a plurality of light-emitting devices each comprising a light-emitting functional layer and a first electrode sequentially stacked in a direction away from the substrate, at least part of the first electrode being located in a corresponding isolation opening;
wherein a part of the first electrode located above the at least one first edge portion and overlapping the isolation structure has a first thickness, and parts of the first electrode located above the plurality of second edge portions have a second thickness that is not greater than the first thickness.
